(19) United States
(12) Patent Application Publication
(10) Pub. No.: US 2003/0197269 A1
(43) Pub. Date: Oct. 23, 2003

(54) Test fixture for semiconductor packages

(75) Inventors: Huan-Ping Su, Hsinchu (TW); Soon-Aik Lu, Hsinchu (TW)

Correspondence Address: EDWARDS & ANGELL, LLP, P.O. BOX 9169, BOSTON, MA, 02209, US

(73) Assignee: UltraTera Corporation, Taiwan (TW)

(21) Appl. No.: 10/192,378

(22) Filed: Jul. 10, 2002

(30) Foreign Application Priority Data
Apr. 18, 2002 (TW) 91107929

(51) Int. Cl. H01L 23/48

(52) U.S. Cl. 257/738

(57) ABSTRACT

A test fixture for semiconductor packages is provided. The test fixture is composed of a circuit board, an interposer and a covering member. The circuit board is used to accommodate semiconductor packages and electrically connect the semiconductor packages to a test device. The interposer is mounted on the circuit board, and formed with through holes for receiving the semiconductor packages therein, wherein each through hole is formed with a positioning mechanism that is engaged with a corresponding semiconductor package received in the through hole, so as to allow the semiconductor package to be firmly held in position within the through hole. The covering member is attached to the interposer, and provided with elastic mechanisms for assuring the semiconductor packages in electrical contact with the circuit board. By using the test fixture, semiconductor packages can be firmly coupled to the test device where functional tests are performed.

### FIELD OF THE INVENTION

The present invention relates to test fixtures for semiconductor packages, and more particularly, to a test fixture for use with BGA (ball grid array) semiconductor packages.

### BACKGROUND OF THE INVENTION

Conventionally, fabricated semiconductor packages are electrically connected by a test fixture to a test device e.g. a test oven for performing various functional tests, such as direct current test, burn-in test, room/cold test, hot sort test, etc; these tests are used to test functionality of the semiconductor packages, for selecting good-quality packages and eliminating inferior products, thereby assuring yield of package fabrication. Since the above functional tests are conventional in the art, they are not to be further described herein.

For performing the functional tests, semiconductor packages to be tested are first mounted on the test fixture; by electrically connecting the test fixture to the test device, the semiconductor packages can be in turn electrically coupled through the test fixture to the test device where a test environment with suitable electricity and other conditions is provided for the semiconductor packages. Therefore, the test fixture plays a critical role in mediating electrical connection between the semiconductor packages and the test device.

FIG. 5 illustrates a conventional test fixture 1 proposed by the present inventor in Taiwan Patent Application No. 91102516. By using the test fixture 1, semiconductor packages 10 e.g. BGA packages are mounted on and electrically connected to a circuit board 11. Then, by electrically connecting the circuit board 11 to a test device (not shown), the semiconductor packages 10 can be electrically coupled via the circuit board 11 to the test device where functional tests are performed. The test fixture 1 is provided with a covering member 12 for covering the semiconductor packages 10 received in through holes 13. The covering member 12 is formed with a plurality of elastic mechanisms 120 that abut against the semiconductor packages 10, such that the semiconductor packages 10 can be held in position within the through holes 13, and input/output (I/O) connections 100 e.g. solder balls of the semiconductor packages 10 can be completely in electrical contact with a plurality of contact terminals 110 formed on the circuit board 11, thereby assuring electrical connection between the semiconductor packages 10 and the circuit board 11.

However, the above conventional test fixture 1 has significant drawbacks. By using only the elastic mechanisms 120 for providing the positioning effect, the semiconductor packages 10 may not be firmly positioned within the through holes 13, and the I/O connections 100 may not be precisely coupled to the corresponding contact terminals 110 of the circuit board 11, thereby deteriorating electrical contact or connection quality between the semiconductor packages 10 and the circuit board 11 or test fixture 1. Moreover, the elastic mechanisms 120 of the covering member 12 may possibly apply excess downward press to the semiconductor packages 10 toward the circuit board 11, making the I/O connections 100 press-damaged by the contact terminals 110, which therefore damages electrical connection between the semiconductor packages 10 and the test fixture 1, thereby undesirably degrading yield of package products.

Therefore, the problem to be solved is to provide a test fixture for assuring electrical connection between semiconductor packages and the test fixture.

### SUMMARY OF THE INVENTION

A primary objective of the present invention is to provide a test fixture for semiconductor packages, whereby semiconductor packages can be firmly electrical connected to the test fixture and a test device where tests are performed, as well as the semiconductor packages can be assured in structural intactness for test performance, thereby maintaining yield of package products.

In accordance with the above and other objectives, the present invention proposes a test fixture for semiconductor packages. The test fixture is used to electrically connect a plurality of BGA (ball grid array) semiconductor packages to a test device where tests are performed for the semiconductor packages.

The test fixture comprises: a circuit board formed on a surface thereof with a plurality of contact mechanisms and electrically connected to the test device, wherein the contact mechanisms are in electrical contact with input/output (I/O) connections of the semiconductor packages, so as to allow the semiconductor packages to be mounted on the circuit board and electrically connected to the test device via the circuit board; an interposer having an upper surface and a lower surface opposed to the upper surface, the interposer being formed with a plurality of through holes that penetrate through the upper and lower surfaces, wherein the lower surface of the interposer is attached to the circuit board in a manner as to receive the semiconductor packages in the through holes respectively, and each of the through holes is formed on an inner wall thereof with an alignment portion that is engaged with a corresponding one of the semiconductor packages received in the through holes, such that the semiconductor packages are held in position within the through holes via the alignment portions, and the input/output connections of the semiconductor packages are assured in electrical contact with the contact mechanisms of the circuit board; and a covering member mounted on the upper surface of the interposer, for covering the semiconductor packages received in the through holes, wherein the covering member is formed with a plurality of elastic mechanisms corresponding in position to the through holes of the interposer, allowing the elastic mechanisms to be interposed between the covering member and the semiconductor packages received in the through holes respectively.

The above test fixture is characterized by forming of the alignment portion for each of the through holes of the interposer, so as to firmly position the semiconductor packages in the through holes. The alignment portion is an incline formed on the inner wall of the through hole in a manner that, an opening of the through hole on the upper surface of the interposer is larger in size than an opposed opening thereof on the lower surface of the interposer. And, the opening of the through hole on the lower surface of the interposer can be dimensioned equally to the semiconductor package, allowing the inclined alignment portion to abut against peripheral edges of the semiconductor package. This allows the semiconductor packages to be firmly held in place within the through holes and on the circuit board, such that the input/output connections of the semiconductor packages can be assured in good electrical contact with the contact mechanisms of the circuit board, unlike the prior art with problems of degraded electrical connection between semiconductor packages and a circuit board due to positional shift or dislocation of the semiconductor packages.

Moreover, the covering member with the plurality of elastic mechanisms is mounted on the interposer. The elastic mechanisms with elastic properties help assure the semiconductor packages in engagement with the alignment portions to be stably positioned within the through holes of the interposer. Therefore, the semiconductor packages can be well electrically connected to the circuit board with cooperation of the alignment portions and the elastic mechanisms, thereby eliminating conventional problems of positional inaccuracy or unstable electrical connection in the only use of elastic mechanisms.

In another embodiment, the alignment portion is formed with a protrusion protruding toward the center of the through hole in a manner that, the protrusion abuts against a surface, formed with the input/output connections, of the semiconductor package, without affecting arrangement of the input/output connections in electrical contact with the contact mechanisms of the circuit board. The protrusion serves as a barrier for counteracting improper downward press from the covering member to the semiconductor package, so as to protect the input/output connections from being press-damaged. Besides the positioning effect, the alignment portion with the protrusion further helps assure structural intactness of the semiconductor package received in the through hole of the interposer, thereby desirably maintaining yield of package products.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram showing perspective and cross-sectional view of components of a test fixture according to a first preferred embodiment of the invention;

FIG. 2 is a cross-sectional view of the test fixture illustrated in FIG. 1 mounted with semiconductor packages;

FIGS. 3A-3D are cross-sectional schematic diagrams showing process steps for mounting the test fixture illustrated in FIG. 1 with semiconductor packages;

FIG. 4 is a cross-sectional view of a test fixture according to a second preferred embodiment of the invention mounted with semiconductor packages; and

FIG. 5 (PRIOR ART) is a cross-sectional view of a conventional test fixture mounted with semiconductor packages.

### DETAILED DESCRIPTION OF THE PREFERRED EMBODIMENT

First Preferred Embodiment

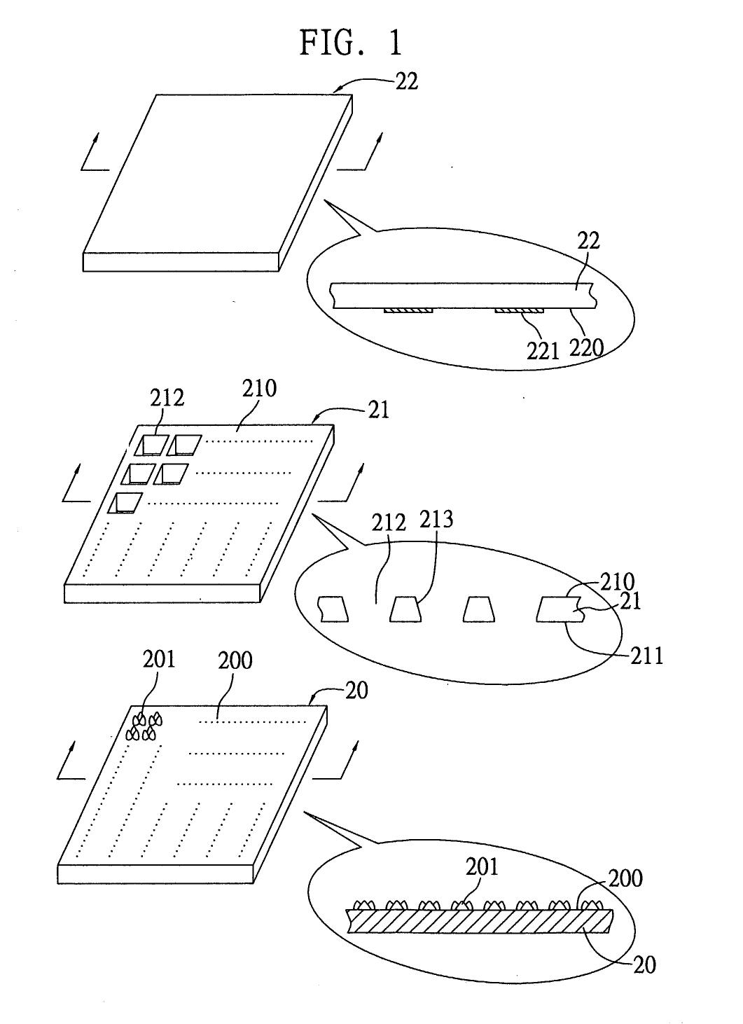

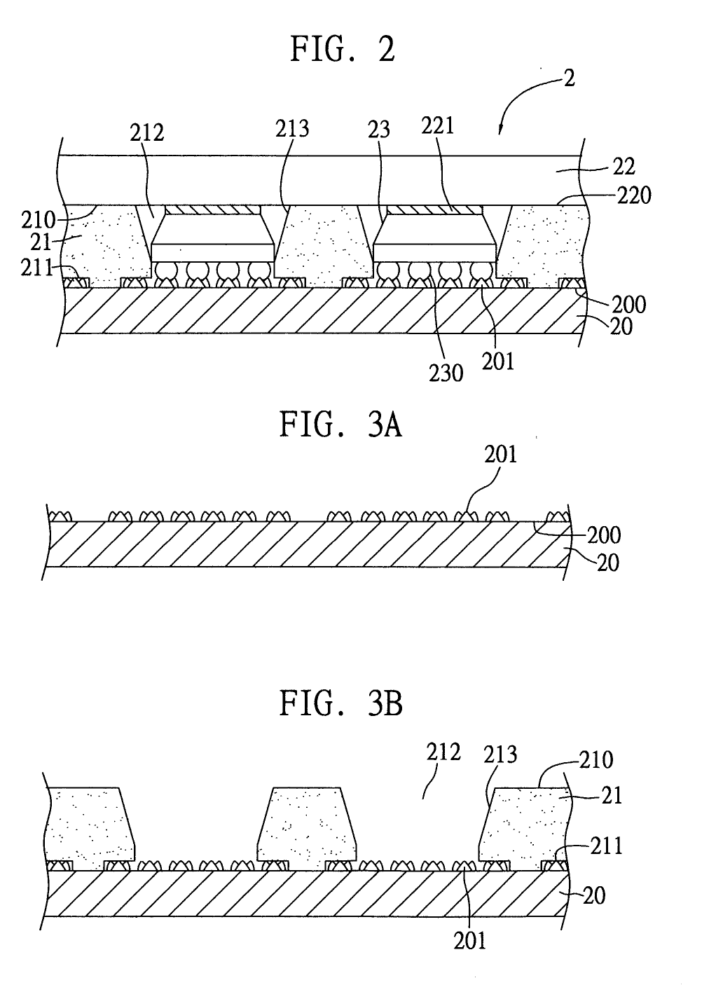

FIGS. 1 and 2 illustrate a test fixture 2 according to a first preferred embodiment of the invention. As shown in FIGS. 1 and 2, the test fixture 2 comprises a circuit board 20, an interposer 21 and a covering member 22, for use to electrically connect a plurality of semiconductor packages 23 e.g. BGA semiconductor packages to a test device (not shown) where functional tests are performed for the semiconductor packages 23.

The circuit board 20 is formed on a surface 200 thereof with a plurality of contact mechanisms 201 e.g. contact terminals, allowing the semiconductor packages 23 to be mounted on the circuit board 20 by coupling input/output (I/O) connections 230 e.g. solder balls of the semiconductor packages 23 to the contact mechanisms 211, so as to electrically connect the semiconductor packages 23 to the test device through the use of the circuit board 20.

The interposer 21 has an upper surface 210 and a lower surface 211 opposed to the upper surface 210, wherein the lower surface 211 is mounted on the circuit board 20. The interposer 21 is formed with a plurality of through holes 212 that penetrate through the upper and lower surfaces 210, 211, so as to receive the semiconductor packages 23 in the through holes 212. The through holes 212 are each formed on its inner wall with an alignment portion 213 that is engaged with a corresponding semiconductor package 23 received in the through hole 212, so as to firmly hold the semiconductor package 23 in position within the through hole 212, allowing I/O connections 230 of the semiconductor package 23 to be in good electrical connection to corresponding contact mechanisms 202 of the circuit board 20.

The covering member 22 is attached to the upper surface 210 of the interposer 21, for covering the semiconductor packages 23 received in the through holes 212, wherein a plurality of elastic mechanisms 221 e.g. elastomer are formed on a surface 220, in contact with the interposer 21, of the covering member 22 corresponding in position to the through holes 212 of the interposer 21 in a manner that, the elastic mechanisms 221 are interposed between the surface 220 of the covering member 22 and the semiconductor packages 23.

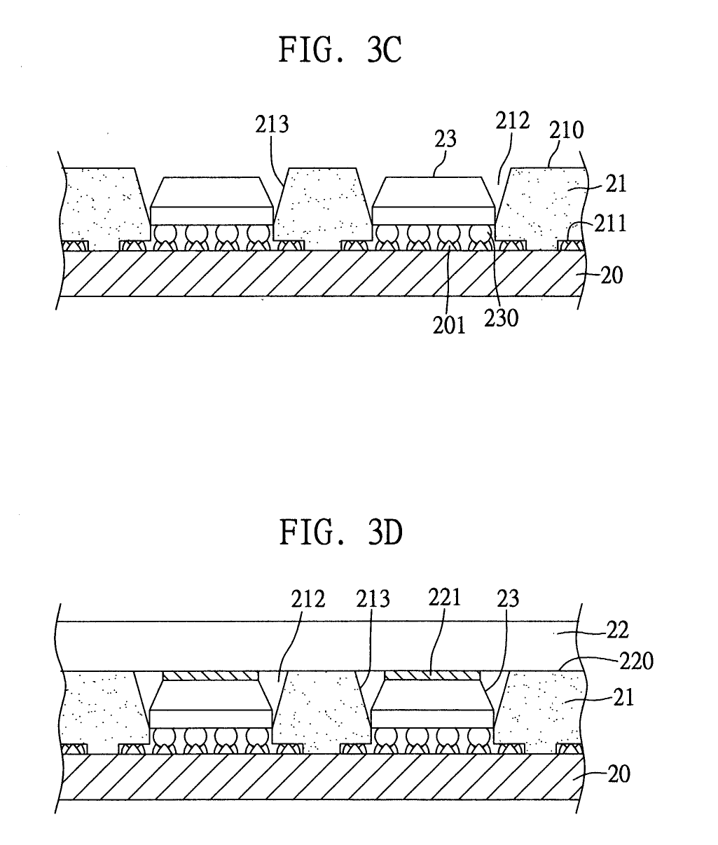

FIGS. 3A-3D illustrate process steps for mounting the above test fixture 2 with semiconductor packages 23.

Referring to FIG. 3A, the first step is to prepare a circuit board 20 formed with a plurality of conductive traces (not shown). The circuit board 20 is formed on a surface 200 thereof with a plurality of contact mechanisms 201 to be in electrical contact with semiconductor packages (not shown) subsequently. The contact mechanisms 201 can be, but not limited to, contact terminals made of an electrically conductive material; it should be understood that, other electrical contact means are also suitably applied herein as the contact mechanisms 201 of the invention.

Referring to FIG. 3B, the next step is to prepare an interposer 21 having an upper surface 210 and a lower surface 211 opposed to the upper surface 210. The interposer 21 is formed with a plurality of through holes 212 that penetrate through the upper and lower surfaces 210, 211, wherein each of the through holes 212 is provided on its inner wall with an alignment portion 213. And, the lower surface 211 of the interposer 21 is attached to the circuit board 20 in a manner as to expose the contact mechanisms 201 of the circuit board 20 to the through holes 212.

The through holes 212 of the interposer 21 are used to receive semiconductor packages (not shown) that are to be mounted on the circuit board 20 subsequently; thus, each of the through holes 212 is dimensioned to be capable of completely accommodating a corresponding semiconductor package therein. The alignment portion 213 of each of the through holes 212 is adapted to be engaged with the semiconductor package, so as to firmly hold the semiconductor package in position within the through hole 212. The alignment portion 213 is an incline formed on the inner wall of the through hole 212 in a manner that, an opening of the through hole 212 on the upper surface 210 is larger in size than an opposed opening thereof on the lower surface 211 of the interposer 21; for example, the opening of the through hole 212 on the lower surface 211 can be dimensioned equally to the semiconductor package, allowing the inclined alignment portion 213 to abut against peripheral edges of the semiconductor package. It should be understood that, other modifications of through holes or alignment portions for the purpose of receiving and positioning semiconductor packages are also pertained to the scope of the invention.

Moreover, the test fixture 2 can be applied to variously sized semiconductor packages in terms of using or replacing a suitable interposer 21 formed with through holes 212 and alignment portions 213 corresponding in dimension to the semiconductor packages, such that the semiconductor packages can be properly received in the through holes 212 and firmly held in position by the alignment portions 213. And, with the interposer 21 being cost-effectively fabricated by simplified processes, the test fixture 2 is further beneficial of reduction in process complexity and fabrication costs thereof.

Referring to FIG. 3C, a plurality of semiconductor packages 23 e.g. BGA semiconductor packages are disposed respectively in the through holes 212 of the interposer 21 in a manner that, input/output (I/O) connections 230 such as solder balls of the semiconductor packages 23 are adapted to be in contact with the contact mechanisms 201 on the circuit board 20, and peripheral edges of the semiconductor packages 23 are engaged with the alignment portions 213 of the through holes 212. This allows the semiconductor packages 23 to be firmly held in place within the through holes 212 and on the circuit board 20, such that the I/O connections 213 can be assured in good electrical contact with the contact mechanisms 201, unlike the prior art with problems of degraded electrical connection between semiconductor packages and a circuit board due to positional shift or dislocation of the semiconductor packages.

Referring finally to FIG. 3D, a covering member 22 is prepared and mounted on the upper surface 210 of the interposer 21, for covering the semiconductor packages 23 received in the through holes 212. The covering member 22 is formed on a surface 220 thereof with a plurality of elastic mechanisms 221 corresponding in position to the through holes 212 of the interposer 21, wherein the elastic mechanisms 221 are adapted to be interposed between the covering member 22 and the semiconductor packages 23. The elastic mechanisms 221 with elastic properties help assure the semiconductor packages 23 in engagement with the alignment portions 213 to be stably positioned within the through holes 212 of the interposer 21. Therefore, the semiconductor packages 23 can be well electrically connected to the circuit board 20 with cooperation of the alignment portions 213 and the elastic mechanisms 221, thereby eliminating conventional problems of positional inaccuracy or unstable electrical connection in the only use of elastic mechanisms.

The elastic mechanisms 221 of the covering member 22 are preferably dimensioned to completely cover the corresponding semiconductor packages 23 respectively, so as to allow the semiconductor packages 23 to be in even contact with the circuit board 20. The elastic mechanisms 221 can be made of elastomer, springs and so on; nevertheless, other elastic means may also be suitably adopted herein for the test fixture 2.

With the semiconductor packages 23 being assembled to the test fixture 2, the semiconductor packages 23 are readily subject to functional tests. By electrically connecting the circuit board 20 of the test fixture 2 to a test device such as a test oven (not shown), the semiconductor packages 23 can be in turn electrically coupled to the test device through the circuit board 20, such that the test device can perform various tests for testing functionality of the semiconductor packages 23. This therefore completes the test method of using the test fixture 2.

Second Preferred Embodiment

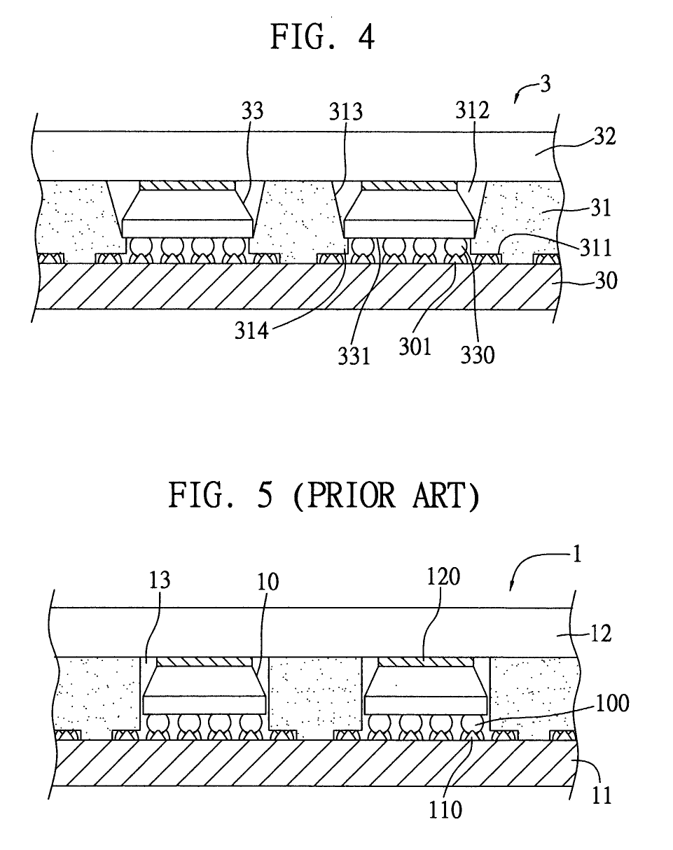

FIG. 4 illustrates a test fixture 3 according to a second preferred embodiment of the invention mounted with semiconductor packages 33. This test fixture 3 of the second embodiment is primarily the same in structure as the test fixture 2 of the first embodiment, except that in the test fixture 3, each alignment portion 313 of an interposer 31 is formed with a protrusion 314 protruding toward the center of a corresponding through hole 312 of the interposer 31. The protrusion 314 is located at an opening of the through hole 213 on a lower surface 311 of the interposer 31, and adapted to support a semiconductor package 33 received in the through hole 312 in a manner that, the protrusion 314 abuts against a surface 331, formed with I/O connections 330, of the semiconductor package 33, without affecting arrangement of the I/O connections 330 in electrical contact with contact mechanisms 301 of a circuit board 30. The protrusion 314 serves as a barrier for counteracting improper downward press from a covering member 32 to the semiconductor package 33, so as to protect the I/O connections 330 from being press-damaged. Besides the improvements rendered in the first embodiment, the alignment portion 313 with the protrusion 314 further helps assure structural intactness of the semiconductor package 33 received in the through hole 312 of the interposer 31, thereby desirably maintaining yield of package products.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A test fixture for semiconductor packages, for electrically connecting a plurality of semiconductor packages to a test device where tests are performed for the semiconductor packages; the test fixture comprising:
a circuit board formed on a surface thereof with a plurality of contact mechanisms and electrically connected to the test device, wherein the contact mechanisms are in electrical contact with input/output connections of the semiconductor packages, so as to allow the semiconductor packages to be mounted on the circuit board and electrically connected to the test device via the circuit board;
an interposer having an upper surface and a lower surface opposed to the upper surface, the interposer being formed with a plurality of through holes that penetrate through the upper and lower surfaces, wherein the lower surface of the interposer is attached to the circuit board in a manner as to receive the semiconductor packages in the through holes respectively, and each of the through holes is formed on an inner wall thereof with a positioning mechanism that is engaged with a corresponding one of the semiconductor packages received in the through holes, such that the semiconductor packages are held in position within the through holes via the positioning mechanisms, and the input/output connections of the semiconductor packages are assured in electrical contact with the contact mechanisms of the circuit board; and
a covering member mounted on the upper surface of the interposer, for covering the semiconductor packages received in the through holes.

2. The test fixture of claim 1, wherein the input/output connections are solder balls.

3. The test fixture of claim 1, wherein the interposer is made of an insulating material.

4. The test fixture of claim 1, wherein each of the through holes of the interposer is dimensioned to allow a corresponding one of the semiconductor packages to be completely received in the through hole.

5. The test fixture of claim 1, wherein the positioning mechanisms is an incline formed on the inner wall of the through hole in a manner that, an opening of the through hole on the upper surface of the interposer is larger in size than an opposed opening thereof on the lower surface of the interposer.

6. The test fixture of claim 5, wherein the opening on the lower surface of the interposer is dimensioned equally to the semiconductor package, allowing the positioning mechanism to abut against peripheral edges of the semiconductor package, so as to firmly position the semiconductor package in the through hole.

7. The test fixture of claim 5, wherein the positioning mechanism is formed with a protrusion protruding toward the center of the through hole in a manner that, the protrusion abuts against a surface, formed with the input/output connections, of the semiconductor package, without affecting arrangement of the input/output connections in electrical contact with the contact mechanisms of the circuit board, and the protrusion serves as a barrier for counteracting improper downward press from the covering member to the semiconductor package, so as to protect the input/output connections from being press-damaged.

8. The test fixture of claim 7, wherein the protrusion is located at the opening of the through hole on the lower surface of the interposer.

9. The test fixture of claim 1, wherein a plurality of elastic mechanisms are formed on the covering member corresponding in position to the through holes of the interposer, and adapted to be interposed between the covering member and the semiconductor packages received in the through holes respectively.

10. The test fixture of claim 9, wherein each of the elastic mechanisms is dimensioned to completely cover a corresponding one of the semiconductor package, so as to allow the semiconductor package to be in even contact with the circuit board.
